(19) United States
(12) Patent Application Publication
(10) Pub. No.: US 2014/0230732 A1
(43) Pub. Date: Aug. 21, 2014

(54) APPARATUS FOR TRANSPORTING SUBSTRATES INTO SUBSTRATE-TREATMENT APPARATUS

(71) Applicant: MANZ AG, Reutlingen (DE)

(72) Inventors: Peter Rettenbacher, Frankfurt (DE); Thomas Merz, Aschaffenburg (DE); Stefan Kastl, Aschaffenburg (DE)

(73) Assignee: MANZ AG, Reutlingen (DE)

(21) Appl. No.: 14/348,033

(22) PCT Filed: Sep. 28, 2012
(86) PCT No.: PCT/EP2012/004092

§ 371 Date: Mar. 27, 2014

(30) Foreign Application Priority Data
Sep. 30, 2011 (DE) 10 2011 114 593.5

(51) Int. Cl. C23C 14/50

(52) U.S. Cl. CPC C23C 14/50
USPC 118/723 R; 118/500; 118/58; 118/729; 118/725

(57) ABSTRACT

A transporting apparatus for simultaneously transporting at least two substrates into a substrate-treatment apparatus to be treated in a vacuum-treatment apparatus has at least two carrier apparatuses mounted for rotation in relation to a common axis and offset axially in relation to one another. At least one retaining frame configured for supporting at least one substrate is arranged on each of the two carrier apparatuses. Each retaining frame is configured to be shifted, by rotary movement of the two carrier apparatuses about the common axis, into mutually opposite regions of a treatment unit with the two carrier apparatuses spaced apart axially from one another sufficiently such that the treatment unit is arranged between the two carrier apparatuses.

### CROSS-REFERENCE TO RELATED APPLICATIONS

This U.S. non-provisional application is the United States national stage of International Application No. PCT/EP2012/004092 filed on Sep. 28, 2012, which claims the benefit of priority of German Application No. 10 2011 114 593.5 filed on Sep. 30, 2011, the entire disclosures of which are incorporated herein by reference.

### FIELD OF THE INVENTION

The present invention relates to a transporting apparatus for simultaneously transporting at least two substrates, which are to be treated, in or on a treatment apparatus. Here, the at least two substrates are mounted rotatably with respect to a common axis, but are offset axially in relation to one another.

### BACKGROUND OF THE INVENTION

Devices for the surface treatment of substrates, in particular for the etching and coating of substrate surfaces, have long been known. For example, chemical vapor deposition (CVD) and physical vapor deposition (PVD) methods, and among these methods plasma-enhanced chemical vapor deposition (PECVD) methods in particular, are used among a large number of conventional coating methods and devices.

In the case of PECVD methods, one or more substrates is/are arranged in a vacuum chamber, into which a reaction gas or a gas mixture matched to the surface treatment is introduced, while predefined pressure and temperature parameters are maintained. By feeding and applying electromagnetic energy, this reaction gas or gas mixture can transition at least in part into a plasma state intended for the respective surface treatment.

Further processes, such as a heating, a cooling and an introduction and/or discharge of the substrate into or from a vacuum region, are typically arranged upstream or downstream of the actual surface-treatment process. It has proven to be expedient to feed the substrates to be treated to individual process stations sequentially by means of a transporting apparatus.

There are different approaches for the arrangement of individual process stations and also for the resultant transport concepts. In the case of the pass-through method, the individual substrates are conveyed in succession usually while retaining their direction of movement through the individual process stations arranged adjacently to one another, for example in a line. With what is known as batch mode, a variety of substrates are fed in each case in packets or stacks to the individual process stations. The pass-through mode and batch mode have proven to be disadvantageous in this respect, since, in order to produce predefined vacuum conditions, the comparatively large volumes of individual process stations each have to be brought to a predefined pressure level.

A vacuum-coating facility for the vapor deposition of thin layers on substrates is known from DE 24 54 544 C4 and comprises a conveying apparatus for transporting the substrates through a number of chambers. Here, the conveying apparatus comprises frames for receiving the substrates, said frames being arranged around a common axis and being pivotable about this axis, wherein such a frame itself forms part of a wall of a treatment chamber at least at two treatment positions, specifically an entry and exit position and in a vapor-deposition position.

Further, a movable valve plate for shutting off an end face of the frame forming part of the treatment chamber is provided in at least one of these treatment positions.

The valve plates provided for sealing off different chambers are provided in this case on opposite sides of an outer housing of the vacuum-coating facility. Here, the outer housing must be designed to be sufficiently stable and warp-resistant so as to be able to provide a counterforce, sufficient to actuate the respective valve plate, in the region of the treatment chamber and also of the entry and exit chambers.

### OBJECTS OF THE INVENTION

By contrast, an object of the present invention is to provide an improved transporting apparatus and also a vacuum-treatment apparatus equipped with same, of which the transport concept enables an improved introduction of force and distribution of force, which are also optimized for the conceptual design of the coating facility, in particular in order to seal off individual process stations. A further object of the invention is to provide a transport concept for a vacuum-treatment apparatus that is improved in terms of transport logistics and that can utilize the treatment capacity of individual process stations to an improved extent and also comprehensively.

### SUMMARY OF THE INVENTION

The objects forming the basis of the invention are achieved with a transporting apparatus according to the exemplary embodiments of the invention shown and described herein and recited in the independent claims appended hereto, wherein advantageous embodiments of the invention are disclosed in each of the dependent patent claims.

The transporting apparatus according to the invention is designed for simultaneously transporting at least two substrates, which are to be treated, in or on a vacuum-treatment apparatus. For this purpose, the transporting apparatus comprises a least two carrier apparatuses which are mounted rotatably with respect to a common axis, but are offset axially in relation to one another based on the axis. At least one retaining frame designed to receive at least one or more substrates is arranged on each of the carrier apparatuses. The two carrier apparatuses can be transferred by a rotary movement about the common axis into the region of a treatment unit that can be arranged between the two carrier apparatuses in the axial direction. The substrates arranged on the retaining frames can thus be transferred into mutually opposed operative regions of the treatment unit and, once the treatment has been carried out, can be further transported along the same or an oppositely directed rotary movement.

A variety of mutually opposed substrates for surface treatment can be arranged on opposite operative regions of a treatment unit and thus on either side of a treatment chamber of the treatment unit by means of the transporting apparatus comprising at least two carrier apparatuses. The capacity utilization or processing capacity of the treatment unit can be considerably increased in this respect. The throughput of substrates to be treated or the treatment capacity can thus be increased and improved advantageously.

Furthermore, an arrangement of the two carrier apparatuses of the transporting apparatus, said arrangement being largely axially symmetrical with respect to a transverse plane, can be provided by means of two carrier apparatuses which are mutually distanced in the axial direction. Any forces to be applied, for example in the axial direction, to the transporting apparatus or to the sealing frames in order to hermetically separate off individual process regions are preferably to be applied here in duplicate and in a manner directed oppositely to one another to the transporting apparatuses distanced from one another in the axial direction. A largely symmetrical (in the axial direction) mechanical force introduction and load distribution can be provided as a result and can prove to be advantageous in particular for the construction of the outer housing, for the operation of the transporting apparatus and for the processes taking place in or on the treatment chamber.

Irrespectively of this and in accordance with a preferred embodiment, a largely synchronous and simultaneous movement of the carrier apparatuses is advantageously provided. Twice the number of substrates can thus be treated in a manner that is unchanged per se, while maintaining a predefined cycle time, which is predefined by the rotary movement as such and by the individual process stations. The throughput of the treatment apparatus can thus be increased by approximately 100% with respect to a transporting apparatus having only one single rotatably mounted carrier apparatus.

In accordance with a development, the retaining frames are designed in particular to transfer the mutually opposed substrates that can be arranged thereon into opposed operative regions of a common treatment unit that can be arranged axially between the carrier apparatuses. In this respect, the substrates, which can be arranged on different carrier apparatuses distanced axially from one another, can be oriented so as to face one another in relation to the axial direction and can therefore be associated with the different mutually opposed axial side or treatment faces of the treatment apparatus that can be arranged between the carrier apparatuses, and can be treated accordingly.

Substrates arranged approximately axially and substantially opposite one another can thus experience a simultaneous treatment by a single common treatment apparatus.

Here, in accordance with a preferred embodiment, the treatment unit comprises a housing which encases a treatment chamber and which can be hermetically isolated with respect to the surrounding environment. To this end, the retaining frames provided on the carrier apparatuses are formed as sealing frames which can be brought into abutment in a sealing manner against opposite housing portions of the treatment chamber.

In accordance with a further embodiment, at least one of the retaining or sealing frames is arranged axially displaceably on the carrier apparatus associated with that frame or receiving that retaining or sealing frame. The respective retaining or sealing frame can be transferred by means of the aforementioned axial displacement into an outwardly sealing abutment position with at least one housing portion of the treatment chamber.

The retaining or sealing frame may preferably be brought here into abutment in a sealing manner with the treatment chamber housing against a restoring force, for example with application of a force acting in the axial direction. If necessary, the sealing frame can revert back into its starting position as a result of decreasing force effect, for example due to a spring-loaded mounting.

In accordance with a further embodiment, at least one of the carrier apparatuses, at least in the region of its at least one retaining frame, may alternatively or additionally be formed or mounted so as to be axially movable relative to the treatment chamber. Here, the carrier apparatus may be formed so as to be axially movable as a whole with respect to the treatment chamber. For example, it may be mounted axially displaceably on the axis. It is also conceivable for the axis or a mount of the carrier apparatus to be mounted axially displaceably with respect to the treatment unit and with respect to the treatment chamber thereof. Lastly, the carrier apparatus, at least in the region of its retaining or sealing frame, may be axially deformable, possibly tiltable with respect to the axis, in order to be able to provide a seal between the treatment chamber housing and retaining or sealing frames of the carrier apparatus.

Alternatively or additionally, the sealing frame itself may also be designed for expansion in the axial direction. For example, the sealing frame, as a result of an application of an expansion medium, such as a gas or a hydraulic fluid, can experience a geometric enlargement and expansion in the axial direction in such a way that a seal can be provided between the sealing frame and treatment chamber housing, even without a relative movement of the sealing frame or carrier apparatus relative to the treatment chamber.

In accordance with a further exemplary embodiment, the transporting apparatus comprises an outer housing surrounding or enclosing the two carrier apparatuses, a lock apparatus for receiving and removing substrates being arranged on each of the outer walls of said outer housing that are opposite in the axial direction. The lock apparatuses formed in an opposed manner on the outer walls of the transporting apparatus come to rest, in an axial projection, preferably in a manner substantially opposite one another.

Here, a synchronous or coupled actuation of the lock apparatuses may also be provided, with the result that any actuation forces acting on the lock apparatuses in the axial direction are directed against one another.

The outer housing provides a hermetic separation and sealing of the transporting apparatus with respect to the outer surrounding environment. Depending on the intended treatment process, the treatment apparatus can be separated with respect to the interior of the outer housing, again hermetically, with use of the sealing frames. In the case of treatment processes that do not require a separate sealing of the treatment volume with respect to the transporting apparatus, retaining frames or similar retaining structures can be used instead of the sealing frames in order to detachably fasten the substrates to the carrier apparatus.

For example, it is thus conceivable that the treatment unit with its treatment chamber is designed to carry out a surface treatment based on sputtering. To this end, a sealing of the treatment chamber with respect to the interior of the outer housing would not be absolutely necessary. That interior should then however have a pressure or vacuum level for the vacuum treatment coordinated with the sputtering process.

Alternatively or additionally, the treatment chamber can be sealed off with respect to the interior of the outer housing, for example so as to carry out a plasma coating process therein. To this end, the interior of the outer housing could lie at atmospheric pressure in principle. However, the interior is preferably held at a predefined pressure level in order to observe cycle times that are as short as possible, in particular to minimize a volume that is to be vacuumed.

In accordance with a further development, the outer housing, in the region of the lock apparatuses preferably coming to rest so as to oppose one another in the axial direction, includes a removable outer lock cover releasing an opening for the substrates. The carrier apparatuses mounted rotatably within the outer housing can be arranged here with their respective sealing frames in line with the opening and can also be brought there into abutment in a sealing manner against the inner face of the outer housing by movements directed in opposite directions from one another in the axial direction (Y). Similarly to the sealing abutment against the treatment chamber housing, the sealing frame can be moved here by a relative displacement of the sealing frame and carrier apparatus, of the carrier apparatus and outer housing, and also by an expansion of the sealing frame or seal thereof.

In accordance with a further development hereof, two inner press plates, which are arranged between the carrier apparatuses and which can function as lock covers, are also arranged displaceably in the axial direction in the region of the lock apparatuses and can be brought into abutment with an inner face of the sealing frames by means of an actuation mechanism, preferably a single actuation mechanism. The actuation mechanism and also the lock covers actuatable thereby are arranged here between the carrier apparatuses, in relation to the axial direction (Y). A simultaneous and oppositely directed actuation and axial displacement of the lock covers can thus advantageously be achieved with just a single actuation mechanism.

A single actuation mechanism is sufficient in this respect in order to move the at least two inner press plates or lock covers largely synchronously or symmetrically in opposite directions and simultaneously with the displacement of the sealing frames of the two carrier apparatuses, it being possible to arrange the sealing frames so as to be aligned with said inner press plates or lock covers. Here, it has in particular proven to be advantageous that the actuation mechanism itself hardly has to apply a counterforce in order to actuate the lock covers.

In accordance with a further development, the actuation mechanism can be arranged in a stationary manner with respect to the outer housing of the transporting apparatus and can be brought into operative connection to both inner press plates or lock covers in order to exert compressive forces directed oppositely to one another. In this respect the actuation mechanism itself does not have to provide a counterforce necessary for actuation of an individual lock cover. It is preferably to be designed to exert compressive forces directed diametrically opposite from one another. To this end, the actuation mechanism may comprise a single cam mechanism operatively connected to both press plates in opposite directions.

The anchoring of the actuation mechanism with respect to the outer housing must not take up any significant forces or deflect any significant forces into the outer housing. Further, the described concept enables a largely simple, and possibly even exchangeable, arrangement of the actuation mechanism in or on the outer housing of the transporting apparatus.

In accordance with a further exemplary embodiment, the carrier apparatuses each include a rotary table extending substantially in a plane perpendicular to the axial direction (Y) and having sealing frames thereon deflectable against a restoring force. The rotary tables extend transversely in relation to the axial direction (Y). Here, the rotary table as such can provide a largely closed planar structure or a skeleton-like carrier structure, on which the at least one sealing frame, but preferably a variety of sealing frames distributed over the plane of the rotary table, is/are provided.

The at least one sealing frame can be mounted in a spring-loaded manner in the axial direction on the rotary table or on the carrier apparatus, for example by means of one or more spring elements. A spring-loaded mounting can be provided in particular by means of a number of extensions extending radially outwardly on the sealing frame and in turn being received displaceably in the axial direction by means of one or more compression springs in a radially inwardly open U- or C-shaped retaining frame of the carrier apparatus.

In accordance with a further exemplary embodiment, the carrier apparatuses, in particular the rotary tables, may further be formed so as to be reversibly deformable in the axial direction, at least in the region of their at least one sealing frame, preferably in the region of all sealing frames. The axial deflection of the sealing frame and/or of the carrier apparatus or of the rotary table may lie in the range of a few millimeters, with the result that a sealing effect can be provided to a sufficient extent in the region of the treatment chamber and/or in the region of the lock apparatuses, possibly even without a displaceable mounting, effective in the axial direction, of sealing frames and/or carrier apparatuses.

In accordance with a further exemplary embodiment, the carrier apparatuses and/or the sealing frames are also oriented substantially vertically and/or the axes about which the carrier apparatuses are rotatable are oriented substantially horizontally. The plane in which the carrier apparatuses are rotatable preferably runs substantially parallel to the force of gravity, with the result that, during their treatment for example in the region of the treatment chamber, the substrates, which can be fastened to different sealing frames, are arranged and oriented largely symmetrically or identically in relation to the effect of the force of gravity.

All substrates, which can be fastened to the different carrier apparatuses, can thus advantageously experience a largely identical treatment in the region of the treatment chamber. In the case of a treatment unit formed as a plasma-treatment station, any effects of gravity, which may sometimes lead to contaminations of the substrate to be coated, can thus additionally be largely avoided or eliminated.

In accordance with a further exemplary embodiment, press apparatuses, which can be brought externally into abutment against the sealing frames and are movable in the axial direction (Y), are provided in the region of the treatment chamber and are designed, during the course of a movement directed toward one another, to transfer the sealing frames of the opposed carrier apparatuses largely symmetrically and synchronously into a sealing abutment position with the treatment chamber.

Similarly to the actuation mechanism provided for the lock actuation, a single press apparatus can also be provided here, by means of which press apparatuses directed oppositely to one another, directed axially inwardly in relation to the treatment chamber and that can be brought externally into abutment against opposed housing portions of the treatment chamber, the press apparatuses being provided for example in the form of press plates or the like, experience a mutual support. The force to be applied in order to actuate a press apparatus, in particular the counterforce corresponding hereto, may advantageously be transferred to the opposite press apparatus.

It has proven here to be advantageous that the outer housing encompassing the treatment chamber in this respect does not have to apply or take up any counterforce necessary for actuation of the press apparatuses.

In accordance with a further exemplary embodiment, the two carrier apparatuses with their sealing frames can also be pivoted into the region of a treatment apparatus, which for example is formed as a heating apparatus and which, on opposite portions of the outer housing of the transporting apparatus, includes two inwardly facing heating elements and/or at least one outwardly directed heating element coming to lie between the carrier apparatuses. The substrates fastened to the transporting apparatus can be heated by means of the heating apparatus, in particular before their treatment in the region of the treatment chamber, to a temperature suitable for the respective treatment process.

At least three individual process stations, specifically a lock, a heating apparatus and a treatment chamber, are preferably provided for the surface-treatment process of the substrates. These process stations are preferably arranged in an equally distributed manner or equidistantly in the peripheral direction of the carrier apparatuses, with the result that, in each retaining position of the transporting apparatus at all process stations, the processing or treatment steps provided there can be carried out simultaneously in each case. The number and relative positions of the individual treatment apparatuses may also vary here. If the surface-treatment process to be carried out can be divided into a number of sub-processes, a plurality of treatment units can be provided on the transporting apparatus in a manner distributed in the peripheral direction.

In accordance with another aspect, the invention further relates to a vacuum-treatment apparatus including a previously described transporting apparatus. The vacuum-treatment apparatus is provided in particular for the surface treatment of the substrates transportable by means of the transporting apparatus. The vacuum-treatment apparatus comprises a treatment unit, preferably including a treatment chamber, further preferably a vacuum or plasma-treatment chamber, which for example is designed to excite a plasma located within the plasma-treatment chamber between at least two substrates to be treated, and which are arranged detachably on different carrier apparatuses.

The retaining frames receiving the substrates can be brought here in the axial direction into opposed treatment or operative regions of the treatment unit, with the result that two opposed substrates arranged on either side of the treatment unit can be treated simultaneously by means of a single treatment unit in accordance with the intended surface-treatment process.

In another exemplary embodiment, the treatment unit is designed to excite a plasma preferably to be formed within a treatment chamber and in any case to be provided between two substrates to be treated. Here, the retaining frames receiving the substrates may preferably be formed as sealing frames and can be brought into abutment in a sealing manner against housing portions of the treatment chamber that are mutually opposed in the axial direction.

Here, the treatment apparatus is in no way limited to plasma-treatment processes, but can be used universally for physical deposition processes (PVD), in particular also for treatment processes based on sputtering. Although an embodiment in which the treatment chamber and interior of the outer housing are sealed or can be sealed with respect to one another may be advantageous, the invention is in no way limited to such embodiments.

Thus, in particular in respect of such surface-treatment processes that are based for example on sputtering, it is equally possible to provide a non-sealing arrangement of individual retaining frames or a plurality of retaining frames with respect to the treatment chamber, in particular with respect to the housing thereof.

In another advantageous embodiment, the plasma-treatment unit includes an excitation coil, which is arranged outside the plasma-treatment chamber but within the outer housing of the transporting apparatus, for inductively exciting a plasma within the treatment chamber. In this respect the interior of the plasma-treatment chamber is formed in a manner free from a plasma-treatment coil. The coil is located fully outside the plasma-treatment chamber in a region in which boundary conditions prevail in such a way that a plasma generation in accordance with Paschen's Law is not possible. If the plasma-treatment unit is formed for example as a coating unit, the coil therefore is not coated as a result of the plasma generation itself.

Furthermore, in accordance with another advantageous embodiment, the plasma-treatment unit with an inner housing enclosing the plasma-treatment chamber can be arranged detachably on the outer housing of the transporting apparatus. In this respect, the plasma-treatment unit with its inner housing can be formed as an exchangeable module, which can be exchanged at will by other treatment modules depending on the requirements of the vacuum-treatment apparatus. A comparable modular embodiment can also be provided here for the heating apparatus, in particular if it consists of a single heating element, or a number of elements coming to rest between the carrier apparatuses in the axial direction.

In accordance with a further exemplary embodiment, the excitation coil surrounds the plasma-treatment chamber in a plane (X, Z) perpendicular to the axial direction (Y). The excitation coil is connected here to an interior of the outer housing of the transporting apparatus. This means that the excitation coil is at the pressure level and in an atmospheric environment prevailing within the outer housing of the transporting apparatus. The inner housing of the plasma-treatment unit, or the plasma-treatment chamber, is separated herefrom hermetically.

Lastly, in another embodiment, the plasma-treatment chamber is in fluid communication with an extraction passing through the inner housing in a connection region to the outer housing. The extraction in fluid communication with the inner housing or with the plasma-treatment chamber consequently passes through the inner housing chamber wall in a housing portion of the plasma-treatment chamber arranged in the region of a receptacle of the outer housing of the transporting apparatus, the receptacle being provided for the plasma-treatment module.

The plasma-treatment chamber arranged largely completely in the interior of the outer housing can thus be coupled to an extraction passing through the outer housing, which makes it possible to provide, within the plasma-treatment chamber, process conditions that are completely different in terms of gas mixture composition and pressure.

In accordance with a further exemplary embodiment, an extraction, which can be brought into fluidic connection to the plasma-treatment chamber, can occur through a press apparatus, by means of which the at least one sealing frame can be brought into a sealing abutment position against the treatment chamber. Here, the press apparatus in particular does not have a closed planar structure, but for example has a spoke-like or skeleton-like structure, by means of which the sealing frame receiving the substrates can be pressed against the treatment chamber housing.

A hermetic separation between the treatment chamber and interior of the transporting apparatus can be implemented here by means of sealing elements which are each arranged in a sealing manner on the one hand on the respective press apparatus and on the other hand on the inner wall of the outer housing. Here, the sealing elements may have a flexibility or mechanical deformability enabling the movement of the sealing frames.

In accordance with a further exemplary embodiment, the treatment unit includes, in a manner offset axially outwardly in relation to the treatment chamber, at least one outer treatment unit, by means of which a side of the at least one substrate facing away from the treatment chamber can be treated. Substrates can thus also be treated simultaneously on both sides. Provided the substrate is held in a sealing manner on the retaining frame, a surface treatment can be carried out on the inner face of the substrate by means of the inner treatment chamber, the surface treatment being different from that carried out on the outer face. Without gas separation, the two opposite sides of the substrate would be treatable in a largely identical manner.

In accordance with a further exemplary embodiment, the outer housing and/or the treatment unit may also include at least one heating element, which is provided to heat a substrate side facing away from the treatment chamber. The substrates would then thus be treatable on both sides in the region of the treatment apparatus. A surface-treatment process could be performed from an inner face, whereas, from a rear face, the substrate is heated and/or is held at a temperature intended for the treatment process.

The described transporting apparatus and the vacuum-treatment apparatus equipped with the transporting apparatus can be used universally, preferably for PECVD coating methods, and also in a large number of further coating and surface-treatment methods, in particular also for sputtering processes. Besides coatings, the aforementioned apparatuses can also be used equally for etching or for cleaning processes without being limited here to plasma-enhanced surface-treatment processes.

It is also conceivable for the treatment unit without separate sealing with respect to the interior of the outer housing to be formed universally for generation of a plasma that is to be formed between opposed substrates. Further, all objects, features and advantages shown, described and claimed with respect to the transporting apparatus are equally valid for the super-ordinate vacuum-treatment apparatus, and vice versa.

### BRIEF DESCRIPTION OF THE DRAWING FIGURES

Further objects, features and advantages for application of the invention will be described in the following detailed description of exemplary embodiments, wherein all features illustrated schematically in the figures and described in the description form part of the subject matter of the present invention.

FIG. 1 shows a sectional illustration of the transporting apparatus from above, viewed with sealing frames located in the starting position.

FIG. 2 shows the transporting apparatus according to FIG. 1 with sealing frames located in the abutment position.

FIG. 3 shows an embodiment, deviating from the embodiment of FIGS. 1 and 2, of the press apparatuses operatively connected to the sealing frame in the region of the plasma-treatment chamber.

FIG. 4 shows an isolated illustration of a possible heating apparatus.

FIG. 5 shows a sectional illustration, corresponding to FIG. 4, of a further embodiment of a heating apparatus.

FIG. 6 shows an isolated illustration of a spring-loaded mounting of a sealing frame bearing against the treatment chamber.

FIG. 7 shows a sealing frame arranged in the starting position in the region of the lock apparatus.

FIG. 8 shows a sealing frame moved outwardly by means of the actuation mechanism into the abutment position with the housing wall in the region of the lock apparatus.

### DETAILED DESCRIPTION OF EMBODIMENTS OF THE INVENTION

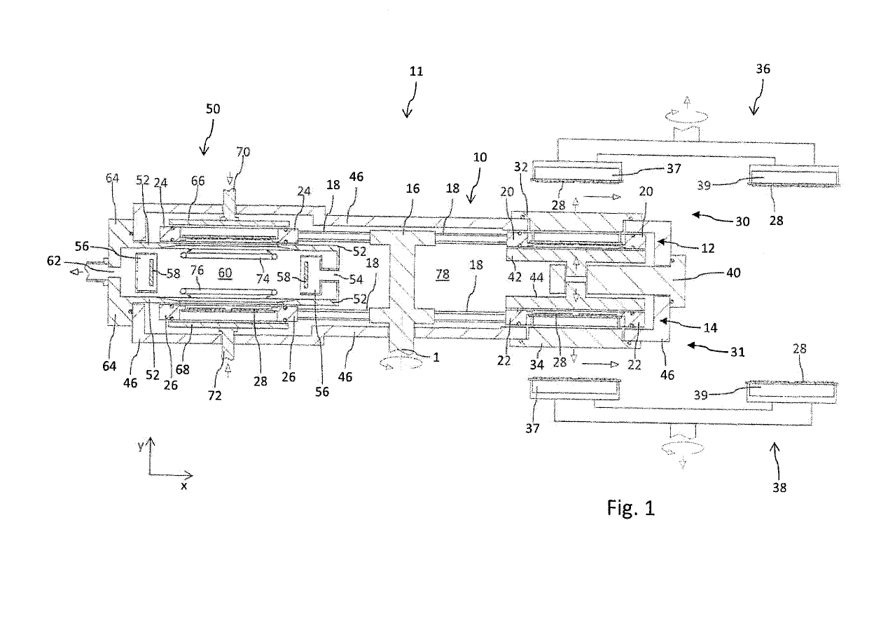

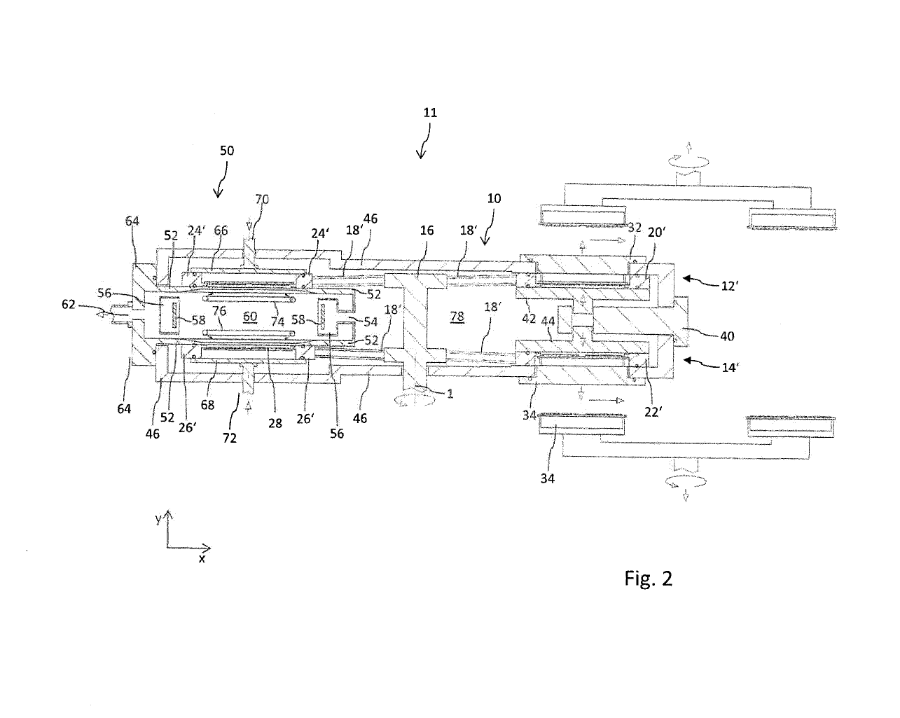

A vacuum-treatment apparatus 11 is shown in cross section from above in FIGS. 1 and 2. The vacuum-treatment apparatus 11 comprises a transporting apparatus 10, which further comprises two carrier apparatuses 12, 14, distanced from one another in the axial direction (Y), and jointly mounted rotatably about an axis 1 extending substantially in the axial direction (Y). In FIG. 1 a cross section is illustrated with two lock apparatuses 30, 31 to the right and a common plasma-treatment unit 50 to the left comprising a plasma-treatment chamber 60.

The carrier apparatuses 12, 14 comprise a supporting structure 18, on which, in accordance with the illustration according to FIGS. 1 and 2, at least two sealing frames 20, 22, 24, 26 movable in the axial direction (Y) are arranged in each case.

As shown herein, all sealing frames 20, 22, 24, 26 comprise, at opposite end portions in relation to the axial direction (Y), seals (not illustrated in greater detail in the figures), for example O-rings, by means of which the individual sealing frames 20, 22, 24, 26 can be sealing in the region of the treatment chamber 60 and in the region of the locks 30, 31, which are opposed in the axial direction (Y). In the case of the vacuum-treatment unit 50, the sealing frames 20, 22, 24, 26 can be brought into abutment externally against the treatment chamber housing 52, and, in the case of the lock apparatuses 30, 31, can be brought into abutment against the inner wall of the outer housing 46 of the transporting apparatus 10 or the vacuum-treatment apparatus 11, in each case in a sealing manner.

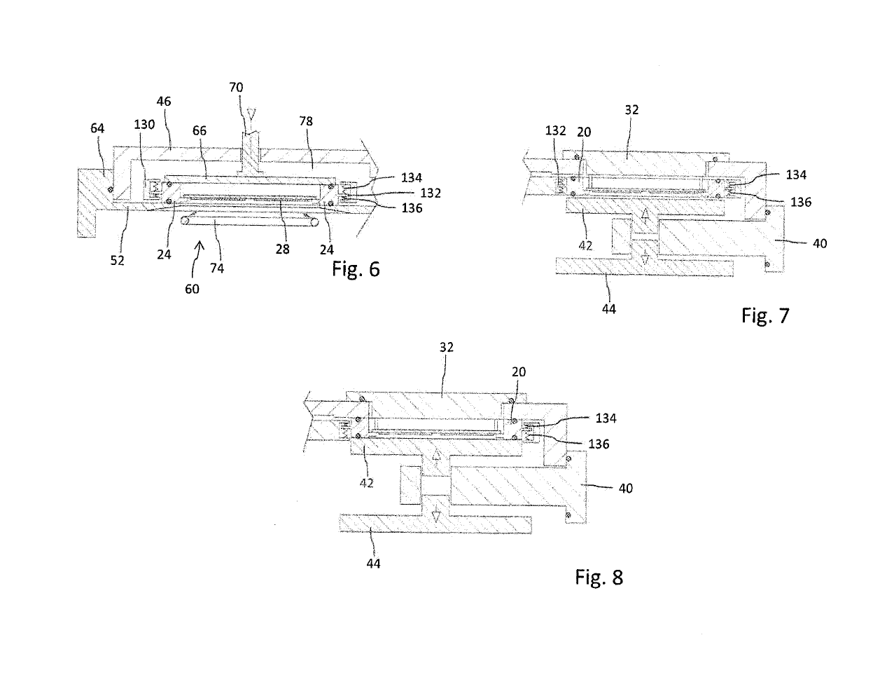

Here, as best illustrated in FIGS. 6, 7 and 8, the individual sealing frames 20, 22, 24, 26 can be mounted displaceably, for example by means of a spring mechanism 134, 136, in the axial direction (Y) on the carrier-side retaining frame 130 against the respective spring force. The sealing frames 20, 24 shown in FIGS. 6 to 8 for this purpose comprise a radially outwardly protruding pin or flange 132, which is located between two compression springs 134, 136 in the axial direction (Y). As illustrated for example in FIG. 6, the sealing frame 24 mounted displaceably on the carrier apparatus can be pressed in a sealing manner against the housing 52 of the plasma-treatment chamber 60 against the force of the spring 136 by means of a press plate 66 extending over the area of the frame 24, and with use of a ram 70, which provides a compressive force directed downwardly in FIG. 6.

Here, the sealing frame 24 seals off hermetically with respect to the chamber wall 52 and also with respect to the press plate 66, with the result that the region formed by the press plate 66 and the sealing frame 24 is in fluid communication with the interior of the plasma-treatment chamber 60, but at the same time is hermetically separated from the rest of the interior 78 of the outer housing 46.

The U-shaped or C-shaped mounts 130 shown in FIGS. 6 to 8 can be connected fixedly to the supporting structure of the carrier apparatuses 12, 14, and can thus be connected immovably in the axial direction to a journal bearing 16 of the transporting apparatus 10.

In the region of the treatment chambers 60, the two sealing frames 24, 26 to be brought into opposed abutment against different sides of the treatment chamber housing 52 are to be brought into abutment in a sealing manner with the housing 52 by means of press plates 66, 68, which can be brought externally into abutment against the sealing frame 24, respectively. The inwardly directed compressive forces necessary for this purpose can be applied here by means of two oppositely directed, substantially symmetrical rams 70, 72. Here, the rams 70, 72 can be coupled to one another outside the outer housing 46 mechanically and in a force-transmitting or force-compensating manner, not shown explicitly, with the result that there is no need for the ram actuation 70, 72 to apply a significant counterforce from the outer housing 46 of the transporting apparatus 10.

In the region of the lock apparatuses 30, 31 illustrated to the right in FIGS. 1 and 2 and coming to rest in a manner opposite one another substantially in the axial direction (Y), an opposite movement of the sealing frames 20, 22 is provided. These sealing frames 20, 22 can be brought externally, that is to say upwardly and downwardly in FIG. 1, into abutment in a sealing manner against the inner wall of the outer housing 46 by means of a respective press plate 42, 44 located between the carrier apparatuses 12, 14 in the axial direction (Y). An actuation mechanism 40 that is merely indicated is designed here to apply compressive forces, directed oppositely to one another, as uniformly as possible to the press plates 42, 44.

Here too, there is no one-sided and asymmetrical mechanical loading of the outer housing 46 or of the bearing journal 16 coupling the carrier apparatuses 12, 14 to one another. Furthermore, merely a single force-applying actuation mechanism 40 is to be provided for the two lock apparatuses 30, 31.

The lock apparatuses 30, 31 arranged opposite one another in the axial direction (Y) each comprise a lock cover 32, 34, which likewise can be brought externally into abutment in a sealing manner against the outer housing 46. In the configuration illustrated schematically in FIG. 2, in which the sealing frames 20′, 22′ each bear in a sealing manner against the outer housing 46, the respective lock cover 32, 34 can be opened in order to remove and/or to receive substrates 28. In FIGS. 1 and 2, an equipping apparatus is also illustrated, which comprises two loading and unloading units 36, 38, each having two substrate retaining apparatuses 37, 39 mounted rotatably thereon.

FIG. 2 shows a simultaneous activation both of the actuation mechanism 40 and of the ram 70, 72, which may lead to an axial deformation, illustrated in an exaggerated manner in FIG. 2, of the carrier structure 18 of the carrier apparatuses 12, 14. Instead of a resiliently deformable embodiment of the carrier apparatuses 12, 14, for example, an application of pressure of the respective sealing frames 20, 22, 24, 26 may be provided, in particular also by means of the spring-mounted embodiment shown in FIGS. 6 to 8.

In accordance with the invention it has proven to be particularly advantageous if a plasma-treatment unit 50 provided for coating purposes and comprising a plasma-treatment chamber 60 is arranged between the substrates 28 disposed at a distance from one another in the axial direction (Y). The plasma-treatment chamber 60 shown in FIGS. 1, 2 and 3 provides an inductive excitation coil 58 arranged outside the chamber, with the result that merely a gas distribution system 74, 76 is arranged within the plasma chamber 60 in order to introduce the process gases to be provided, for example for performing a coating process.

Here, the interior of the plasma-treatment chamber 60 is enclosed annularly in the Y-Z plane by the plasma-generating coil 58 arranged outside the chamber. Here, the coil 58 is atmospherically connected to the interior 78 of the outer housing 46, whereas the interior of the plasma-treatment chamber 60 is hermetically separated therefrom and can be operated at a completely different pressure level by means of an extraction 62.

The excitation coil 58 arranged outside the plasma-treatment chamber further has the advantage that, for the inductive excitation of the plasma, there is no need to arrange electrodes, necessary for plasma formation, within the vacuum chamber. The substrate holders provided in order to hold the substrates 28 and held detachably on the sealing frames 20, 22, 24, 26 can also be formed completely independently of the plasma source itself.

The plasma source, in particular the excitation coil 58, is formed here so as to couple electromagnetic energy into the plasma-treatment chamber 60 in such a way that a gas mixture forming the plasma can be operated exclusively in what is known as the H-mode, or can burn in the H-mode. A characterizing feature of the inductive excitation provided here in a preferred manner is that the H-mode predominates in the plasma, but at least that a noticeable portion, preferably a predominant portion, of the energy transfer to the plasma occurs via what is known as the H-mode. For a more detailed explanation of the H-mode, reference is made at this juncture for example to the dissertation composed by Victor Kadetov “Diagnostics and Modeling of an Inductively Coupled Radio Frequency Discharge in Hydrogen”, Fakultät für Physik and Astronomie, Ruhr-Universität Bochum 2004”, pages 14 ff.

In accordance with the embodiment according to FIGS. 1 to 3, the entire plasma-treatment chamber 60 along with the inner housing 52 thereof can also be inserted modularly and detachably into the outer housing 46 of the transporting apparatus 10. As viewed from the left outwards, the inner housing 52 in FIG. 1 transitions into a widened flange portion 64, by means of which the plasma-treatment unit or module 50 can be arranged so as to rest in a sealing manner against the outer housing 46 and with its plasma-treatment chamber within the outer housing 46 between the carrier apparatuses 12, 14 in the axial direction (Y).

The plasma-treatment unit 50 further comprises an annular chamber 56, which is open outwardly via a passage 54 and in which the excitation coil 58 is arranged. Due to the passage 54, the annular chamber 56 is in fluid communication with the interior 78 of the housing 46. Boundary conditions of this type, in terms of gas composition and pressure level, are created in the interior 78 and therefore also in particular in the annular chamber 56, with the result that, if a high frequency is applied to the excitation coil 58, a plasma ignition condition according to Paschen's law is not created in the interior 78. Plasma ignition or plasma generation can thus be limited advantageously to the interior of the plasma-treatment chamber 60.

The volume provided for receiving the excitation coil 58 and referred to as an annular chamber 56 does not in any way have to be formed here in a radially symmetrical or annular manner. It may also be formed so as to be arranged rectangular or in a square manner in the transverse plane (X, y), in particular in accordance with the substrate geometry and treatment chamber geometry. In all of the embodiments illustrated herein, a Y-axis denoting the axial direction extends in the horizontal direction, with the result that a plane of rotation of the carrier apparatuses 12, 14 and the plane of the substrates 28 to be treated lie substantially parallel to the direction of gravity.

In the embodiment according to FIGS. 1, 2 and 3, the press plates 66, 68, which can be brought into abutment with the sealing frames 24, 26 and are displaceable inwardly toward the chamber interior, form a treatment chamber housing wall facing away from the substrates 28.

The press plates 66, 68 hermetically seal off the chamber interior 60 with respect to the housing interior 78. Process gases are extracted from the treatment chamber 60 via the extraction 62, which is guided in a region through the housing of the plasma-treatment unit 50, said region simultaneously penetrating the outer housing 46 of the transporting apparatus 10 in the radial direction.

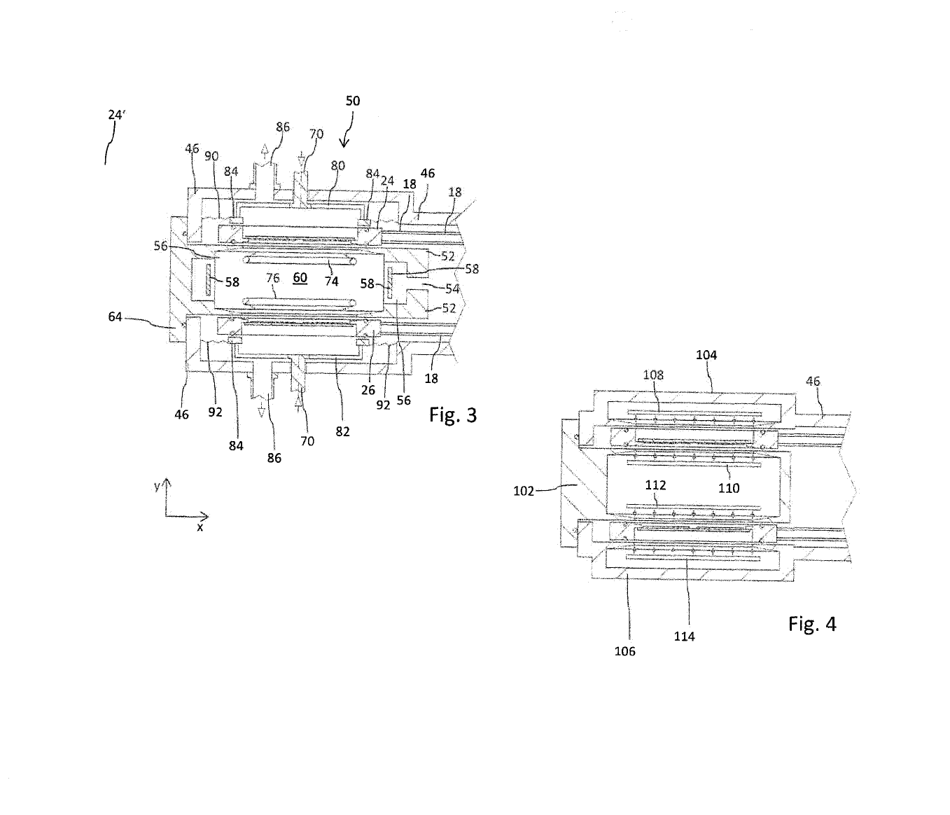

A configuration deviating therefrom is shown in FIG. 3. Here, an annular chamber 56 incorporated into the housing 52 of the plasma-treatment chamber 60 is also provided. However, extraction takes place here through the press apparatuses 80, 82 in abutment with the sealing frames 24, 26. The press pieces 84 of the press apparatuses 80, 82 coming into abutment with the sealing frames 24, 26 are connected in a sealing manner to the inner wall of the outer housing 46 via separation elements 90, 92 formed in a flexible manner. The press apparatuses 80, 82 themselves are gas-permeable here so as to enable an extraction 86, 88 protruding in the axial direction on the outer housing 46. Of course, a vacuum-treatment apparatus provided with its own extraction 62, as is shown in FIGS. 1 and 2, here may also replace the vacuum-treatment apparatus shown in FIG. 3. The extraction of the treatment chamber 60 would then be possible both in the radial and in the axial direction via a total of the three extraction pipes 62, 86, 88.

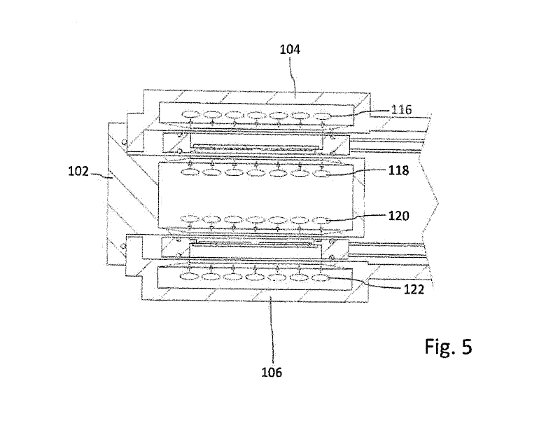

Lastly, two different embodiments of conceivable heating apparatuses 100 are shown in FIGS. 4 and 5 that may likewise function as a treatment unit. In accordance with the embodiment according to FIG. 4, a heating module 102 fitted with two sheet-type heating elements 110, 112 is inserted here radially inwardly into a receptacle, provided for this purpose, of the outer housing 46 of the transporting apparatus 10. At the same time, opposed indentations 104, 106, for example in order to receive further sheet-type heating elements 108, 114 can be provided in the region of the outer housing 46, with the result that the substrates arranged substantially one above the other in the axial direction (Y) can be heated from both sides, together with their mounts provided for this purpose, to a predefined temperature level.

FIG. 5 shows an embodiment similar to FIG. 4, wherein all sheet-type heating elements 110, 112 are replaced however by individual radiant heaters 116, 118, 120, 122. Here, it is conceivable in principle that the heating apparatuses 100 can be formed variably both with heating elements 110, 112 and 118, 120 arranged between the substrates and also exclusively with heating elements 108, 114, 166, 122 provided or arranged outside and in a stationary manner on the outer housing 46.

It goes without saying that the type of heating apparatus is of course also coordinated with the treatment process to be carried out in the plasma-treatment chamber 60. The lock apparatuses 30, 31, the plasma-treatment unit 50 with its plasma-treatment chamber 60, and also the heating apparatus 100 are distributed, preferably uniformly, in the peripheral direction of the carrier apparatuses 12, 14, that is to say are distributed for example by 120°.

If further process stations, not illustrated explicitly in the drawing figures, should be provided, this of course results in an alternating arrangement, deviating herefrom, of treatment unit 50, locks 30, 31 and heating apparatus 100.

1. A transporting apparatus for simultaneously transporting at least two substrates to be treated in a vacuum-treatment apparatus, comprising;
at least two carrier apparatuses mounted rotatably with respect to a common axis and offset axially in relation to one another;
at least one retaining frame arranged on each of the carrier apparatuses to receive at least one substrate;
wherein the retaining frames arranged on each of the carrier apparatuses are configured to be brought by a rotary movement of the carrier apparatuses about the common axis, into mutually opposed operative regions of a treatment unit; and
wherein the carrier apparatuses are spaced apart axially from one another sufficiently such that the treatment unit can be arranged therebetween.

2. The transporting apparatus as claimed in claim 1, wherein the retaining frames transfer the mutually opposed substrates arranged on each of the retaining frames into opposed operative regions of a common treatment unit arranged axially between the carrier apparatuses.

3. The transporting apparatus as claimed in claim 2, wherein the retaining frames are formed as sealing frames configured for being brought into abutment in a sealing manner against opposed housing portions of a treatment chamber of the treatment unit.

4. The transporting apparatus as claimed in claim 1, wherein at least one of the retaining frames is arranged axially displaceably on its associated carrier apparatus.

5. The transporting apparatus as claimed in claim 3, wherein at least one of the carrier apparatuses, at least in the region of the at least one retaining frame, is mounted so as to be axially movable relative to the treatment chamber.

6. The transporting apparatus as claimed in claim 1, further comprising an outer housing surrounding the carrier apparatuses, a lock apparatus configured for receiving and removing substrates provided on each of the outer walls of said outer housing that are arranged opposite in the axial direction.

7. The transporting apparatus as claimed in claim 6, wherein the outer housing, in the region of the lock apparatuses, in each case comprises a removable outer lock cover releasing an opening for the substrates, and the carrier apparatuses are arranged with their respective retaining frame in line with the opening and in each case configured for being brought into abutment in a sealing manner against the inner face of the outer housing by movements directed in opposite directions from one another in the axial direction.

8. The transporting apparatus as claimed in claim 7, wherein two inner press plates are arranged between the carrier apparatuses displaceably in the axial direction in the region of the lock apparatuses and configured for being brought into abutment with an inner face of the retaining frames by means of an actuation mechanism.

9. The transporting apparatus as claimed in claim 8, wherein the actuation mechanism is arranged in a stationary manner with respect to the outer housing and is configured for being brought into operative connection to both inner press plates in order to exert compressive forces directed oppositely to one another.

10. The transporting apparatus as claimed in claim 1, wherein the carrier apparatuses each comprise a rotary table extending substantially in a plane perpendicular to the axial direction with the retaining frames thereon deflectable against a restoring force.

11. The transporting apparatus as claimed in claim 1, wherein the carrier apparatuses are formed so as to be reversibly deformable in the axial direction, at least in the region of the at least one retaining frame.

12. The transporting apparatus as claimed in claim 1, wherein at least one of the carrier apparatuses and the retaining frames are oriented substantially vertically and corresponding common axis is oriented substantially horizontally.

13. The transporting apparatus as claimed in claim 3, wherein each of the sealing frames arranged in the region of the treatment chamber is configured to be transferred, facing one another, into the sealing abutment position with the treatment chamber by means of at least one press apparatus coming into abutment externally with the sealing frame and movable in the axial direction.

14. The transporting apparatus as claimed in claim 6, wherein the carrier apparatuses with their retaining frames are configured to be pivoted into the region of a heating apparatus, which comprises in each case two inwardly facing heating elements on opposed portions of the outer housing and at least one outwardly facing heating element arranged between the carrier apparatuses.

15. A vacuum-treatment apparatus comprising the transporting apparatus according to claim 1 and further comprising at least one treatment unit having a treatment chamber and arranged between the at least two carrier apparatuses of the transporting apparatus in the axial direction, and configured to simultaneously treat substrates arranged by means of the transporting apparatus in mutually opposed operative regions of the treatment unit.

16. The vacuum-treatment apparatus as claimed in claim 15, wherein the treatment unit is configured to excite a plasma generated between at least two oppositely arranged substrates.

17. The vacuum-treatment apparatus as claimed in claim 15, wherein the retaining frames of the carrier apparatuses are formed as sealing frames of the transporting apparatus and are configured to be brought into abutment in a sealing manner against a housing of the treatment chamber.

18. The vacuum-treatment apparatus as claimed in claims 15, wherein the treatment unit comprises an excitation coil arranged outside the treatment chamber to inductively excite a plasma generated within the treatment chamber.

19. The vacuum-treatment apparatus as claimed in claim 15, wherein the treatment unit is provided with an inner housing arranged detachably on an outer housing.

20. The vacuum-treatment apparatus as claimed in claim 19, wherein the excitation coil surrounds the treatment chamber in a plane perpendicular to the axial direction and is connected to an interior of the outer housing.

21. The vacuum-treatment apparatus as claimed in claim 19, wherein the treatment chamber is in fluid communication with an extraction passing through the inner housing in a region of connection to the outer housing.

22. The vacuum-treatment apparatus as claimed in claim 15, wherein an extraction configured to be brought into fluid communication with the treatment chamber through a press apparatus so that the at least one retaining frame is transferred into a sealing abutment position against the treatment chamber.

23. The vacuum-treatment apparatus as claimed in claim 15, wherein the treatment unit comprises at least one outer treatment unit offset axially outwardly in relation to the treatment chamber so as to treat a side of the at least one substrate facing away from the treatment chamber.

24. The vacuum-treatment apparatus as claimed in claim 19, wherein the outer housing and/or the treatment unit comprise at least one heating element provided to heat a side of the at least one substrate facing away from the treatment chamber.
